(19) United States
(12) Patent Application Publication
(10) Pub. No.: US 2006/0292876 A1
(43) Pub. Date: Dec. 28, 2006

(54) Plasma etching method and apparatus, control program and computer-readable storage medium

(75) Inventor: Wakako Naito, Nirasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/471,699

(22) Filed: Jun. 21, 2006

Related U.S. Application Data
(60) Provisional application No. 60/698,016, filed on Jul. 12, 2005.

(30) Foreign Application Priority Data
Jun. 21, 2005 (JP) 2005-180720

(51) Int. Cl. C23F 1/00; G06F 19/00; G03C 5/04; H01L 21/302

(52) U.S. Cl. 438/689; 700/121; 430/396; 216/41; 156/345.47

(57) ABSTRACT

In a method for plasma etching a wafer laminated with a target layer, a lower organic layer, an intermediate layer and an upper resist layer in that order from bottom, the method includes following steps: patterning the upper resist layer by exposure and development, plasma etching the intermediate layer by using the patterned upper resist layer as a mask, plasma etching the lower organic layer by using the intermediate layer as a mask, and plasma etching the target layer by using the lower organic layer as a mask. While the intermediate layer is etched, since reaction products are deposited on the sidewalls of the openings in the intermediate layer, the sidewalls of the openings in the intermediate layer are tapered. In addition, because the dimensions (bottom CD) of the openings in the intermediate layer are smaller than those of the upper resist layer, it is possible to form openings in the target layer smaller than those of the upper resist layer.

### FIELD OF THE INVENTION

The present invention relates to a plasma etching method and apparatus, a control program and a computer-readable storage medium, for forming, e.g., a hole in a target layer such as a silicon oxide layer by using a multilayer resist process.

### BACKGROUND OF THE INVENTION

In a conventional manufacture of semiconductor devices, a hole, e.g., a contact hole is formed in a silicon oxide layer by plasma etching. In such contact hole forming process, there has been known a method of patterning a KrF resist in a predetermined pattern by exposing and developing to obtain a resist mask and performing plasma etching by using the resist mask.

Further, in order to keep up with a trend of miniaturization of circuit patterns of semiconductor devices, there has also been proposed a multilayer resist process using laminated mask layers of an upper resist layer, e.g., ArF resist capable of transcribing a finer pattern, an inorganic intermediate layer and a lower resist layer.

In the multilayer resist process described above, it has been conventionally known that a plasma etching of a small critical dimension difference (ACD) is performed to allow the pattern of the upper resist layer to be transcribed on a lower resist layer accurately. (See, e.g., Japanese patent Laid-open publication No. H9-270419.)

However, as the semiconductor devices become miniaturized, widths of wirings and diameters of contact holes, which form circuits thereof, tend to be smaller. Therefore, the development of the plasma etching method is required for finely patterning the target layer.

### SUMMARY OF THE INVENTION

It is, therefore, an object of the present invention to provide a plasma etching method and apparatus, a control program and a computer-readable storage medium, wherein a target layer can be etched into a finer pattern compared with the conventional one.

In accordance with a preferred embodiment of the present invention, there is provided a method for plasma etching a target object including a target layer and mask layers of a lower organic layer, an intermediate layer, and an upper resist layer stacked on the target layer in that order from the bottom, the method including the steps of:

patterning the upper resist layer by exposure and development; plasma etching the intermediate layer by using the patterned upper resist layer as a mask; plasma etching the lower organic layer by using the intermediate layer as a mask; and plasma etching the target layer by using the lower organic layer as a mask, wherein dimensions of openings formed in the intermediate layer are smaller than dimensions of corresponding openings formed in the upper resist layer.

In accordance with another preferred embodiment of the present invention, there is provided a method for plasma etching a target object including a target layer and mask layers of a lower organic layer, an intermediate layer, and an upper resist layer stacked on the target layer in that order from the bottom, the method including the steps of:

patterning the upper resist layer by exposure and development; plasma etching the intermediate layer by using the patterned upper resist layer as a mask; plasma etching the lower organic layer by using the intermediate layer as a mask; and plasma etching the target layer by using the lower organic layer as a mask, wherein dimensions of openings formed in the lower organic layer are smaller than dimensions of corresponding openings formed in the upper resist layer.

Preferably, sidewalls of the openings in the intermediate layer are tapered.

Preferably, the plasma etching of the intermediate layer is performed while reaction products are deposited on the sidewalls of the openings in the intermediate layer.

In accordance with still another preferred embodiment of the present invention, there is provided a method for plasma etching a target object including a target layer and mask layers of a lower organic layer, an intermediate layer, and an upper resist layer stacked on the target layer in that order from the bottom, the method including the steps of:

patterning the upper resist layer by exposure and development; plasma etching the intermediate layer by using the patterned upper resist layer as a mask; plasma etching the lower organic layer by using the intermediate layer as a mask; and plasma etching the target layer by using the lower organic layer as a mask, wherein, by using a plasma etching apparatus respectively applying high-frequency powers to a support electrode supporting the target object and an opposite electrode located to face the support electrode and controlling the high-frequency powers applied to the opposite electrode when plasma etching the intermediate layer, reaction products are deposited on sidewalls of the openings in the intermediate layer, so that the sidewalls of the openings in the intermediate layer are tapered.

In accordance with still another preferred embodiment of the present invention, there is provided a method for plasma etching a target object including a target layer and mask layers of a lower organic layer, an intermediate layer, and an upper resist layer stacked on the target layer in that order from the bottom, the method including the steps of:

patterning the upper resist layer by exposure and development; plasma etching the intermediate layer by using the patterned upper resist layer as a mask such that sidewalls of openings in the intermediate layer are tapered; plasma etching the lower organic layer by using the intermediate layer as a mask; and plasma etching the target layer by using the lower organic layer as a mask.

Preferably, by using a plasma etching apparatus respectively applying high-frequency powers to a support electrode supporting the target object and an opposite electrode located to face the support electrode and by adjusting the high-frequency power on the opposite electrode, dimensions of the openings formed in the intermediate layer are controlled.

Preferably, an etching gas used in plasma etching the intermediate layer is a gas mixture including CF₄ and CHF₃.

Preferably, the dimensions of the openings in the intermediate layer are controlled by adjusting a ratio of CF₄ to CHF₃ in the etching gas.

Preferably, the dimensions of the openings in the intermediate layer are controlled by adjusting a time period for plasma etching the intermediate layer.

In accordance with still another preferred embodiment of the present invention, there is provided a control program, executed on a computer, for controlling a plasma etching apparatus to perform the above-described methods.

In accordance with still another preferred embodiment of the present invention, there is provided a computer-readable storage medium storing a control program executed on a computer, wherein the control program controls a plasma etching apparatus to perform the above-described methods.

In accordance with still another preferred embodiment of the present invention, there is provided a plasma etching apparatus including:

a processing chamber accommodating a target object therein; an etching gas supply unit for supplying an etching gas into the processing chamber; a plasma generating unit for converting the etching gas supplied from the etching gas supply unit into a plasma-state to etch the target object; and a control unit for controlling the plasma etching apparatus to perform the above-described methods.

### BRIEF DESCRIPTION OF THE DRAWINGS

The above and other objects and features of the present invention will become apparent from the following description of preferred embodiments, given in conjunction with the accompanying drawings, in which:

FIG. 1 is a schematic diagram showing a plasma etching apparatus in accordance with the present invention;

FIGS. 2A to 2C are cross sectional views of a semiconductor wafer, which illustrate the steps of an etching process in accordance with the present invention;

FIG. 3 is a graph showing the relationship between a bottom CD and an upper electric power in accordance with Experiments 1 to 3 of the present invention;

FIG. 4 is a graph showing the relationship between a bottom CD and a flow rate ratio of an etching gas in accordance with Experiments 4 and 5 of the present invention;

FIG. 5 is a graph showing the relationship between a bottom CD and a pressure in accordance with Experiments 6 and 7 of the present invention; and

FIG. 6 is a graph showing the relationship between a bottom CD and an etching time in accordance with Experiment 8 of the present invention.

### DETAILED DESCRIPTION OF THE PREFERRED EMBODIMENT

Hereinafter, preferred embodiments of the present invention will be described in detail with reference to the accompanying drawings.

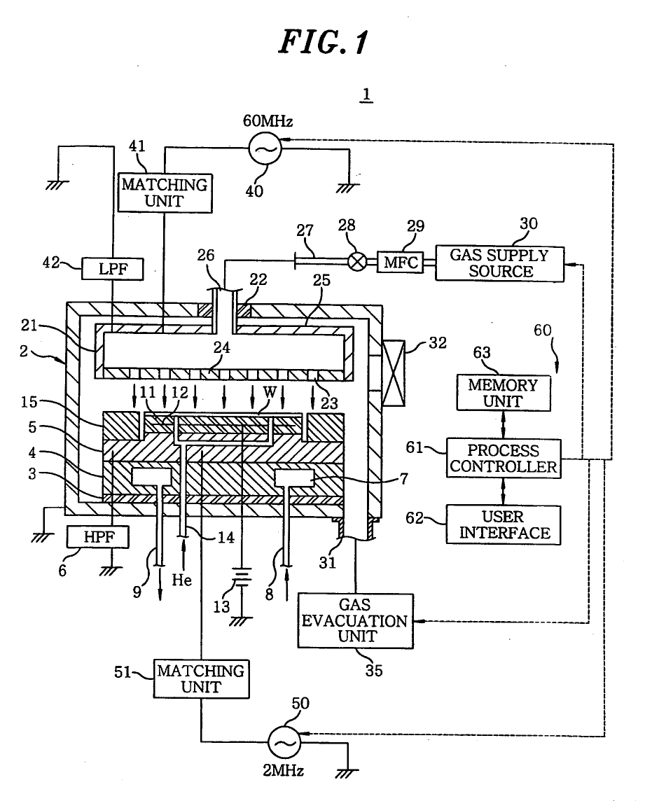

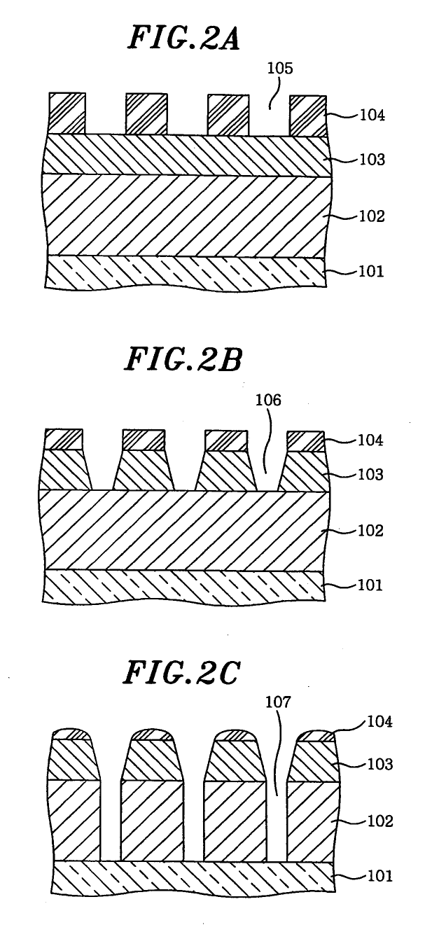

FIG. 1 is a schematic diagram showing a plasma etching apparatus in accordance with the present invention, and FIGS. 2A to 2C are enlarged cross sectional views of a semiconductor wafer W. First of all, a plasma etching apparatus 1 will be described with reference to FIG. 1.

The plasma etching apparatus 1 is constructed as a capacitively coupled parallel plate type etching apparatus wherein electrode plates are vertically arranged so as to face each other, and a plasma generating power supply is connected to one of them.

The plasma etching apparatus 1 includes, e.g., a cylindrical processing chamber 2 which is made of aluminum thermally sprayed with yttrium oxide. The processing chamber 2 is grounded. An approximately columnar susceptor support 4 is provided via an insulating plate 3 formed of, e.g., a ceramic on the bottom of the processing chamber 2. And, a susceptor 5 serving as a lower electrode is provided on the susceptor support 4. A high pass filter (HPF) 6 is connected to the susceptor 5.

In the susceptor support 4, a coolant chamber 7 is provided. A coolant is introduced into the coolant chamber 7 through a coolant introducing line 8 to be circulated. At that time, the cold heat of the coolant is transferred to the wafer W via the susceptor 5, so that the wafer W is controlled to a desired temperature.

The susceptor 5 is provided at its upper central portion with a disk-shaped protrusion, and an electrostatic chuck 11 having almost the same shape as the wafer W is provided thereon. The electrostatic chuck 11 is structured such that an electrode 12 is embedded in an insulation material. When a DC voltage of 1.5 kV is applied to the electrode 12 from a DC power supply 13 connected thereto, the wafer W is electrostatically held on the electrostatic check 11 by, e.g., the Coulomb force.

A gas channel 14 for supplying a heat transfer medium, e.g., He gas, to a backside of the wafer W is formed through the insulating plate 3, the susceptor support 4, the susceptor 5 and the electrostatic chuck 11. The cold heat is transferred to the wafer W from the susceptor 5 via the heat transfer medium, thereby allowing the wafer W to be maintained at a predetermined temperature.

On the upper periphery of the susceptor 5, an annular focus ring 15 is provided so as to surround the wafer W held on the electrostatic chuck 11. The focus ring 15 is made of a conductive material, e.g., silicon, and serves to improve etching uniformity.

An upper electrode 21 is arranged above the susceptor 5 so as to face the susceptor 5 in parallel thereto. The upper electrode 21 is held by an insulting member 22 at the upper portion in the processing chamber 2. The upper electrode 21 includes an electrode plate 24 and an electrode support 25 for holding the electrode plate 24. The electrode plate 24 faces the susceptor 5 and has a plurality of injection holes 23 formed therethrough. The electrode plate 24 is made of aluminum whose surface is anodized (alumited) and covered with quartz. The electrode support 25 is made of a conductive material. The distance between the susceptor 5 and the upper electrode 21 is adjustable.

A gas introduction port 26 is provided at the central portion of the electrode support 25 of the upper electrode 21, and is connected to a gas supply line 27. Moreover, the gas supply line 27 is connected to a gas supply source 30 via a valve 28 and a mass flow controller 29. An etching gas for plasma etching is supplied from the gas supply source 30. The etching gas for plasma etching is, e.g., a gas mixture of CF₄, CHF₃ and Ar, and a gas mixture of N₂ and O₂.

A gas exhaust line 31 is connected to the bottom of the processing chamber 2, and the gas exhaust line 31 is also connected to a gas evacuation unit 35. The gas evacuation unit 35 includes a vacuum pump such as a turbo-molecular pump and is configured to depressurize the inside of the processing chamber 2 to a predetermined level, e.g., less than 1 Pa. A gate valve 32 is installed at the sidewall of the processing chamber 2. Accordingly, while the gate valve 32 is opened, the wafer W is transferred between the processing chamber 2 and a load-lock chamber (not shown) nearby.

A first high-frequency power supply 40 is connected to the upper electrode 21, and a matching unit 41 is interposed therebetween. Further, a low pass filter (LPF) 42 is connected to the upper electrode 21. The first high-frequency power supply 40 outputs a power of a frequency ranging from 13 to 150 MHz. By applying such a high-frequency power, it is possible to produce a high-density plasma in a desirable dissociation state in the processing chamber 2. The frequency of the first high-frequency power supply 40 preferably ranges from 13 to 80 MHz. In Experiments with respect to the preferred embodiments of the present invention which will be described later, the frequency of 60 MHz as shown in FIG. 1 is used.

A second high-frequency power supply 50 is connected to the susceptor 5 serving as the lower electrode via a matching unit 51. The second high-frequency power supply 50 outputs a power of a lower frequency range than that of the first high-frequency power supply 40. By applying the power of a frequency in such range, a suitable ion action is generated without damaging the target semiconductor wafer W. The frequency of the second high-frequency power supply 50 preferably ranges from 1 to 20 MHz. In the Experiments which will be described later, the frequency of 2 MHz as shown in FIG. 1 is used.

The operations of the plasma etching apparatus 1 constructed as described above are generally controlled by a control unit 60. The control unit 60 includes a user interface 62, a memory unit 63 and a process controller 61 having a CPU to controll each part of the plasma etching apparatus 1.

The user interface 62 includes a keyboard which is used by a process operator in inputting commands for controlling the plasma etching apparatus 1, and a display for displaying the operation status of the plasma etching apparatus 1.

The memory unit 63 stores recipes including a control program (software) for controlling various processes executed by the plasma etching apparatus 1 with the control of the process controller 61 and process condition data. If necessary, the operator selects a recipe from the memory unit 63 by using the user interface 62 to be executed by the process controller 61, so that a desired process is performed in the plasma etching apparatus 1 under the control of the process controller 61. The recipes including the control program and the process condition data may be stored in a computer-readable storage medium (e.g., a hard disc, a compact disc, a flexible disc, a semiconductor memory and the like) or may be transmitted online from other devices through a dedicated line, for example.

When various films formed on the semiconductor wafer W are etched by using the plasma etching apparatus 1 constructed as described above, the wafer W is first transferred into the processing chamber 2 from the load-lock chamber (not shown) to be mounted on the electrostatic chuck 11 after the gate valve 32 is opened. Thereafter, by applying the DC voltage from the high-voltage DC power supply 13 to the electrostatic chuck 11, the wafer W is electrostatically adsorbed thereon. Subsequently, the gate valve 32 is closed and the processing chamber 2 is evacuated by the gas evacuation unit 35 to a desired vacuum level.

Then, after the valve 28 is opened, the etching gas from the gas supply source 30 is introduced into the upper electrode 21 via the gas supply line 27 and the gas introduction port 26, while its flow ratio is adjusted by the mass flow controller 29 and the etching gas is uniformly injected toward the wafer W through the injection holes 23 of the electrode plate 24 as shown by using the arrows in FIG. 1.

The pressure in the processing chamber 2 is maintained at a predetermined level. Thereafter, a high-frequency power of a predetermined frequency is applied to the upper electrode 21 from the first high-frequency power supply 40. As a result, a high-frequency electric field is generated between the upper electrode 21 and the susceptor 5 serving as the lower electrode, so that the etching gas is dissociated to become a plasma-state.

Meanwhile, from the second high-frequency power supply 50, a high-frequency power of a lower frequency than that of the first high-frequency power supply 40 is applied to the susceptor 5 serving as the lower electrode. As a result, since ions in plasma are attracted toward the susceptor 5, an etching anisotropy becomes higher due to ion-assist effect.

Further, after the etching process is finished, the application of the high-frequency power and the supply of the etching gas are stopped, and the wafer W is unloaded out of the processing chamber 2 in the reverse order to that described above.

Next, with reference to FIGS. 2A to 2C, a plasma etching method in accordance with a preferred embodiment of the present invention will be described.

As shown in FIG. 2A, a target layer 101 (TEOS (tetra ethyl ortho silicate) film in this embodiment) is formed on the surface of the wafer W as the target object. On the target layer 101, a lower organic layer 102 (KrF resist film in this embodiment), an intermediate layer 103 (silicon oxide film (SOG) in this embodiment) and an upper resist layer 104 (ArF resist film in this embodiment) are formed in that order from the bottom to form laminated mask layers. The upper resist layer 104 is patterned in a predetermined pattern so as to have a plurality of openings 105 therethrough. The openings 105 are formed by exposing and developing the upper resist layer 104.

In a plasma etching method in accordance with this embodiment of the present invention, first of all, the intermediate layer 103 is etched to be in the state as shown in FIG. 2B by using the upper resist layer 104 as a mask. In this plasma etching, the openings 106 in the intermediate layer 103 are formed to have tapered sidewalls and a gas mixture of CF₄, CHF₃ and Ar is used as the etching gas. The openings 106 in the intermediate layer 103 become tapered since reaction products are deposited on the sidewall thereof while the etching is progressed in the depth direction thereof. Accordingly, the dimensions (bottom CD) of the openings in the intermediate layer 103 become smaller than those of the upper resist layer 104.

Subsequently, the lower organic layer (KrF resist film) 102 is etched to be in the state as shown in FIG. 2C by using the intermediate layer 103 as a substantial mask. An etching gas used in this plasma etching is, e.g., a gas mixture of N₂ and O₂. At this time, as described above, since the dimensions (bottom CD) of the openings in the intermediate layer 103 are smaller than those of the upper resist layer 104, the dimensions (bottom CD) of the openings in the lower organic layer 102 are smaller than those of the upper resist layer 104.

Thereafter, the target layer 101 (TEOS film) is etched by using the lower organic layer 102 as a substantial mask. As a result, it is possible to make the dimensions (top CD and bottom CD) of the openings formed in the target layer 101 smaller than dimensions (bottom CD) of the openings in the upper resist layer 104.

(Experiment 1)

By using the plasma etching apparatus 1 shown in FIG. 1, in the semiconductor wafer W shown in FIG. 2A, the intermediate layer 103 was etched to be in the state shown in FIG. 2B under the following conditions.

In addition, the following process recipe stored in the memory unit 63 or a storage medium was read out therefrom by the control unit 60 of the plasma etching apparatus 1, and the etching process was performed based on the following recipe.

| | |
|---|---|
| Etching gas: | CF₄/CHF₃/Ar = 50/50/200 sccm |
| Pressure: | 13.3 Pa (100 mTorr) |
| Electric power: | upper/lower = 500/200 W |
| Distance between the electrodes: | 35 mm |
| Temperature (lower/upper/sidewall) = | 30/30/50° C. |
| Pressure of He gas for cooling | 1330/4655 Pa |
| (center/periphery) = | (10/35 Torr) |
| Time: | 70 seconds |

As a result, compared with 135 nm of the dimensions (bottom CD) of the openings in the patterned upper resist layer 104, the dimensions (bottom CD) of the openings in the intermediate layer 103 were 118 nm at the central portion of the wafer W and 122 nm at the peripheral portion of the wafer W. By observing the cross sections of the openings with an electron microscope, it has been found that sidewalls of the openings in the intermediate layer 103 are tapered.

Thereafter, from the state shown in FIG. 2B, the lower organic layer 102 was etched to be in the state of FIG. 2C under the following conditions by using the intermediate layer 103 as the substantial mask.

| | |
|---|---|
| Etching gas: | N₂/O₂ = 100/20 sccm |
| Pressure: | 1.33 Pa (10 mTorr) |
| Electric power: | upper/lower = 1400/300 W |
| Distance between the electrodes: | 60 mm |
| Temperature (lower/upper/sidewall) = | 30/30/50° C. |
| Pressure of He gas for cooling | 1330/4655 Pa |
| (center/periphery) = | (10/35 Torr) |
| Time: | 53 seconds |

As a result, compared with 135 nm of the dimensions (bottom CD) of the openings in the patterned upper resist layer 104, the dimensions (bottom CD) of openings in the lower organic layer 102 were 128 nm at the central portion of the wafer W and 125 nm at the peripheral portion of the wafer W. By plasma etching the target layer 101 with the lower organic layer 102 as the substantial mask, it becomes possible to make the opening dimension of the target layer 101 smaller than that of the upper resist layer 104. In other words, it becomes possible to form, in the target layer 101, the openings 107 of a smaller diameter or the recesses of a narrower width than those in the patterned upper resist layer 104.

(Experiment 2)

The same plasma etching process was performed on the intermediate layer 103 under the same conditions as those in the Experiment 1 except that the upper electric power was increased to 1000 W. As a result, compared with 135 nm of the dimensions (bottom CD) of the openings in the patterned upper resist layer 104, the dimensions (bottom CD) of the openings in the intermediate layer 103 were 112 nm at the central portion of the wafer W and 112 nm at the peripheral portion of the wafer W. By observing the cross sections of the openings with the electron microscope, it has been found that sidewalls of the openings in the intermediate layer 103 are tapered. In addition, after plasma etching the lower organic layer 102, the dimensions (bottom CD) of the openings in the lower organic layer 102 were 122 nm at the central portion of the wafer W and 120 nm at the peripheral portion of the wafer W.

(Experiment 3)

The same plasma etching process was performed on the intermediate layer 103 under the same conditions as those in the Experiment 1 except that the upper electric power was increased to 1500 W. As a result, compared with 135 nm of the dimensions (bottom CD) of the openings in the patterned upper resist layer 104, the dimensions (bottom CD) of the openings in the intermediate layer 103 were 100 nm at the central portion of the wafer W and 98 nm at the peripheral portion of the wafer W. By observing the cross sections of the openings with the electron microscope, it has been found that sidewalls of the openings in the intermediate layer 103 are tapered. In addition, after plasma etching the lower organic layer 102, the dimensions (bottom CD) of the openings in the lower organic layer 102 were 121 nm at the central portion of the wafer W and 120 nm at the peripheral portion of the wafer W.

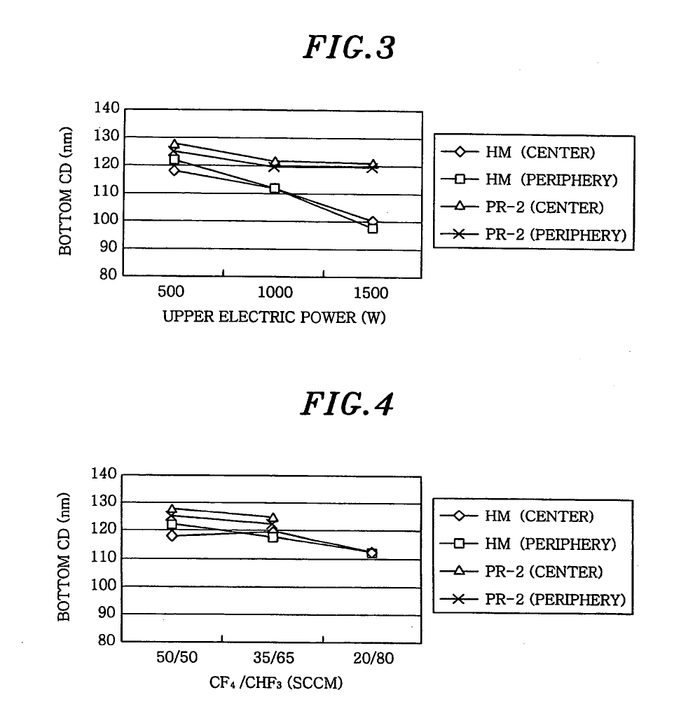

As stated above, in Experiments 1 to 3, the intermediate layer 103 could be etched such that the sidewalls of openings were tapered. Accordingly, compared with the dimensions (bottom CD) of the openings of the patterned upper resist layer 104, it was possible to make the dimensions (bottom CD) of the openings in the intermediate layer 103 smaller. In this plasma etching, since the etching was progressed in the depth direction while reaction products were deposited on the sidewalls of the openings, the sidewalls became tapered. Further, as can be seen from a graph of FIG. 3 wherein the Y-axis represents the bottom CD and the X-axis represents the upper electric power, it was possible to control the dimensions (bottom CD) of the openings in the intermediate layer 103 by varying the upper electric power applied to the upper electrode 21. That is, by increasing the upper electric power, the dimensions (bottom CD) of the openings in the intermediate layer 103 could be decreased. Moreover, in the graph of FIG. 3 and graphs of FIGS. 4 to 6 which will be described later, HM represents the intermediate layer 103 and PR-2 represents the lower organic layer 102.

In this way, by performing the plasma etching on the lower organic layer 102 by using, as a substantial mask, the intermediate layer 103 having the small opening dimensions (bottom CD), the dimensions (bottom CD) of the openings in the intermediate layer 103 could be made smaller than those of the patterned upper resist layer 104. Thus, by plasma etching the target layer 101 by using the lower organic layer 102 as a substantial mask, it became possible to form therein openings or recesses having smaller dimensions than the dimensions (bottom CD) of the openings in the upper resist layer 104.

(Experiments 4 and 5)

Further, as for the etching gas of CF₄, CHF₃ and Ar used in plasma etching the intermediate layer 103, the plasma etching was performed under the condition that the flow rate ratio of CF₄ to CHF₃ was changed from 50:50 in Experiment 1 to 35:65 (Experiment 4) and 20:80 (Experiment 5) (the other conditions were the same as those in Experiment 1). Then, the dimensions (bottom CD) of the openings in the intermediate layer 103 were measured. Results in Experiments 4 and 5 were as follows.

Experiment 4
The flow rate ratio of CF₄ to CHF₃=35:65
The dimensions (bottom CD) at the central portion of the wafer W=120 nm
The dimensions (bottom CD) at the peripheral portion of the wafer W=118 nm

Experiment 5
The flow rate ratio of CF₄ to CHF₃=20:80
The dimensions (bottom CD) at the central portion of the wafer W=112 nm
The dimensions (bottom CD) at the peripheral portion of the wafer W=112 nm

Referring to the above results, it was able to further decrease the dimensions (bottom CD) of the openings in the intermediate layer 103 by increasing the flow rate of CHF₃ while decreasing the flow rate of CF₄ in the etching gas. As such, by changing the flow rate ratio of CF₄ to CHF₃, the dimensions (bottom CD) of the openings in the intermediate layer 103 could also be controlled. In a graph of FIG. 4, the Y-axis and the X-axis represent the bottom CD and the flow rate ratio of CF₄ to CHF₃, respectively, to show the relationship therebetween.

(Experiments 6 and 7)

Furthermore, the plasma etching was performed on the intermediate layer 103 under the condition that the pressure of 13.3 Pa in Experiment 1 was changed to 6.65 Pa (Experiment 6) and 4.4 Pa (Experiment 7) (the other conditions were the same as those in Experiment 1). The dimensions (bottom CD) of the openings in the intermediate layer 103 were measured. Results in Experiment 6 and 7 were as follows.

Experiment 6
The pressure=6.65 Pa
The dimensions (bottom CD) at the central portion of the wafer W=115 nm
The dimensions (bottom CD) at the peripheral portion of the wafer W=117 nm

Experiment 7
The pressure=4.4 Pa
The dimensions (bottom CD) at the central portion of the wafer W=118 nm
The dimensions (bottom CD) at the peripheral portion of the wafer W=120 nm

As can be seen from Experiments 6 and 7, similar effects were obtained in the pressure range of 4.4 to 13.3 Pa. Therefore, the dimensions (bottom CD) of the openings were not greatly influenced by the pressure difference. In a graph of FIG. 5, the Y-axis and the X-axis represent the bottom CD and the pressure, respectively, to show the relationship therebetween.

(Experiment 8)

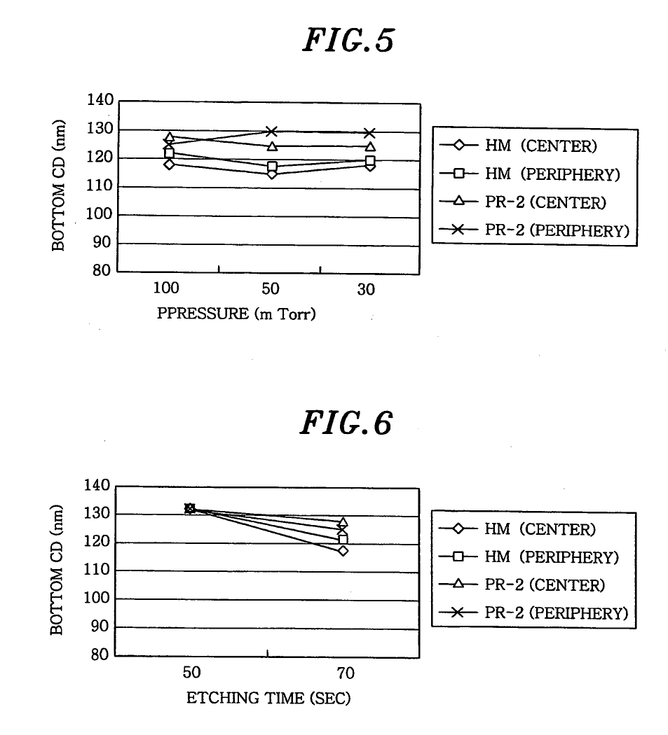

The intermediate layer 103 was etched under the condition that the etching time was shortened from 70 sec to 50 sec while the other conditions remained same as those in Experiment 1. As a result, the dimensions (bottom CD) of the openings in the intermediate layer 103 were 132 nm at central portion of the wafer W, and 132 nm at the peripheral of the wafer W. Further, as a result of etching the lower organic layer 102 by using the intermediate layer 103 as the substantial mask, the dimensions (bottom CD) of the openings in the lower organic layer 102 were 132 nm at the central portion of the wafer W and 132 nm at the peripheral portion of the wafer W. As can be seen from above results, by shortening the etching time, the opening dimensions (bottom CD) tended to increase. Therefore, the opening dimensions (bottom CD) can be controlled by changing the etching time. In a graph of FIG. 6, the Y-axis and the X-axis represent the bottom CD and the etching time, respectively, to show the relationship therebetween.

While the invention has been shown and described with respect to the preferred embodiments, it will be understood by those skilled in the art that various changes and modification may be made without departing from the scope of the invention as defined in the following claims.

What is claimed is:

1. A method for plasma etching a target object including a target layer and mask layers of a lower organic layer, an intermediate layer, and an upper resist layer stacked on the target layer in that order from the bottom, the method comprising the steps of:
patterning the upper resist layer by exposure and development;
plasma etching the intermediate layer by using the patterned upper resist layer as a mask;
plasma etching the lower organic layer by using the intermediate layer as a mask; and
plasma etching the target layer by using the lower organic layer as a mask,
wherein dimensions of openings formed in the intermediate layer are smaller than dimensions of corresponding openings formed in the upper resist layer.

2. A method for plasma etching a target object including a target layer and mask layers of a lower organic layer, an intermediate layer, and an upper resist layer stacked on the target layer in that order from the bottom, the method comprising the steps of:
patterning the upper resist layer by exposure and development;
plasma etching the intermediate layer by using the patterned upper resist layer as a mask;
plasma etching the lower organic layer by using the intermediate layer as a mask; and
plasma etching the target layer by using the lower organic layer as a mask,
wherein dimensions of openings formed in the lower organic layer are smaller than dimensions of corresponding openings formed in the upper resist layer.

3. The method of claim 1, wherein sidewalls of the openings in the intermediate layer are tapered.

4. The method of claim 1, wherein the plasma etching of the intermediate layer is performed while reaction products are deposited on the sidewalls of the openings in the intermediate layer.

5. A method for plasma etching a target object including a target layer and mask layers of a lower organic layer, an intermediate layer, and an upper resist layer stacked on the target layer in that order from the bottom, the method comprising the steps of:
patterning the upper resist layer by exposure and development;
plasma etching the intermediate layer by using the patterned upper resist layer as a mask;
plasma etching the lower organic layer by using the intermediate layer as a mask; and
plasma etching the target layer by using the lower organic layer as a mask,
wherein, by using a plasma etching apparatus respectively applying high-frequency powers to a support electrode supporting the target object and an opposite electrode located to face the support electrode and controlling the high-frequency powers applied to the opposite electrode when plasma etching the intermediate layer, reaction products are deposited on sidewalls of the openings in the intermediate layer, so that the sidewalls of the openings in the intermediate layer are tapered.

6. A method for plasma etching a target object including a target layer and mask layers of a lower organic layer, an intermediate layer, and an upper resist layer stacked on the target layer in that order from the bottom, the method comprising the steps of:
patterning the upper resist layer by exposure and development;
plasma etching the intermediate layer by using the patterned upper resist layer as a mask such that sidewalls of openings in the intermediate layer are tapered;
plasma etching the lower organic layer by using the intermediate layer as a mask; and
plasma etching the target layer by using the lower organic layer as a mask.

7. The method of claim 6, wherein, by using a plasma etching apparatus respectively applying high-frequency powers to a support electrode supporting the target object and an opposite electrode located to face the support electrode and by adjusting the high-frequency power on the opposite electrode, dimensions of the openings formed in the intermediate layer are controlled.

8. The method of claim 6, wherein an etching gas used in plasma etching the intermediate layer is a gas mixture including CF₄ and CHF₃.

9. The method of claim 8, wherein the dimensions of the openings in the intermediate layer are controlled by adjusting a ratio of CF₄ to CHF₃ in the etching gas.

10. The method of claim 6, wherein the dimensions of the openings in the intermediate layer are controlled by adjusting a time period for plasma etching the intermediate layer.

11. A control program, executed on a computer, for controlling a plasma etching apparatus to perform the plasma etching method described in claim 6.

12. A computer-readable storage medium storing a control program executed on a computer, wherein the control program controls a plasma etching apparatus to perform the plasma etching method described in claim 6.

13. A plasma etching apparatus comprising:
a processing chamber accommodating a target object therein;
an etching gas supply unit for supplying an etching gas into the processing chamber;
a plasma generating unit for converting the etching gas supplied from the etching gas supply unit into a plasma-state to etch the target object; and
a control unit for controlling the plasma etching apparatus to perform the plasma etching method described in claim 6.
